(19) United States
(12) Patent Application Publication
(10) Pub. No.: US 2009/0146319 A1
(43) Pub. Date: Jun. 11, 2009

(54) SEMICONDUCTOR DEVICE

(75) Inventors: Takamitsu ONDA, Chuo-ku (JP); Kazuhiko MATSUKI, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 12/327,099

(22) Filed: Dec. 3, 2008

(30) Foreign Application Priority Data
Dec. 6, 2007 (JP) 2007-315943

(51) Int. Cl. H01L 23/495

(52) U.S. Cl. 257/782; 257/E23.037

(57) ABSTRACT

A semiconductor device which can prevent damage to an ESD protection device by pressure when bonding is carried out, while having a pad configuration that can ensure bonding reliability, with the semiconductor device being made as small as possible. A bonding area that is an area for wire bonding with respect to an external electrode pad and a probing area that is an area in which a probe needle is applied when probing, are provided, and the ESD protection device and a discharge path therefor are arranged below the probing area. Arranged below the bonding area are a support via that is a little smaller than the bonding pad, and a support pattern having a size corresponding to the bonding pad and joined to the bonding pad by the support via.

### REFERENCE TO RELATED APPLICATION

This application is based upon and claims the benefit of the priority of Japanese patent application No. 2007-315943, filed on Dec. 6, 2007, the disclosure of which is incorporated herein in its entirety by reference thereto.

### BACKGROUND OF THE INVENTION

1. Field of the Invention

The present invention relates to a semiconductor device provided with an ESD protection device for preventing damage to an internal element due to electrostatic noise incoming from an external electrode pad.

2. Description of Related Art

Conventionally, in order to reduce the size of a semiconductor device provided with an ESD protection device, technology is proposed in which the ESD protection device is formed below a bonding pad (for example, refer to Patent Documents 1 through 3).

Moreover, although not related to a semiconductor device that has a pad electrode, there is a proposal of a structure which considers as a problem, damage produced by a probe needle when probing is carried out, and divides a bump electrode for an external connection for a flip chip into a region for the probing and a region for connecting (refer to Patent Document 4).

### [Patent Document 1]:

JP Patent Kokai Publication No. JP-P2000-133775A

### [Patent Document 2]:

JP Patent Kokai Publication No. JP-A-11-307724

### [Patent Document 3]:

JP Patent Kokai Publication No. JP-P2003-289104A

### [Patent Document 4]:

JP Patent Kokai Publication No. JP-A-5-129305

### SUMMARY

The entire disclosures of above Patent Documents are incorporated herein by reference thereto. The following analysis are given according to the views of the present invention.

In the semiconductor devices of Patent Document 1 through Patent Document 3, one electrode pad is a bonding target, and also a probing target; however, in these semiconductor devices, there is a risk of a contact defect occurring when bonding is carried out, that is, a risk of bonding reliability decreasing, due to damage by the probe needle as indicated in Patent Document 4.

For example, since MobileRAM or the like is shipped in a wafer state, conventionally, testing and evaluation carried out after package assembly are performed in the wafer state. Therefore, in MobileRAM and the like, the number of times probing is carried out on the electrode pad increases, and contact damage due to the probe needle also increases. The increase in contact damage due to the probe needle in the electrode pad causes effective contact area of the bonding wire and the electrode pad to decrease when bonding is carried out, and as a result, there is a possibility that the bonding reliability will decrease, as described above.

As a means of preventing this decrease in the bonding reliability, for example, a configuration in which one electrode pad has an area (bonding area) for wire bonding, and an area (probing area) to which a probe needle is applied in probing, can be considered, but with such a configuration an increased pad size cannot be avoided, and therefore chip size becomes large.

On the other hand, the semiconductor devices of Patent Document 1 through Patent Document 3 provide an ESD protection device below a bonding pad, aiming to reduce chip size, but since a load of approximately 20 to 300 grams acts on the bonding pad when bonding is carried out, there is a risk of the ESD protection device being damaged, and therefore arrangement of the ESD protection device below the bonding pad is not preferable.

It is desired to provide a semiconductor device in which it is possible to prevent damage to an ESD protection device by pressure when bonding is carried out, while having a pad configuration that can ensure bonding reliability, with the semiconductor device being made as small as possible.

In a first aspect of the semiconductor device according to the present invention, the semiconductor device includes: an external electrode pad having a bonding area that is an area for wire bonding and a probing area that is an area to which a probe needle is applied in probing; and an ESD protection device positioned below the probing area and arranged to be electrically connected to the probing area.

Furthermore, in a second aspect of the semiconductor device according to the present invention, a semiconductor device is obtained in which, in the semiconductor device according to the first aspect, the ESD protection device is formed so as not to be positioned directly below the bonding area.

Furthermore, in a third aspect of the semiconductor device according to the present invention, a semiconductor device is obtained in which the semiconductor device according to the first or the second aspect is further provided with a discharge path connected to the ESD protection device, and the discharge path is arranged so as not to be positioned directly below the bonding area.

Furthermore, in a fourth aspect of the semiconductor device according to the present invention, a semiconductor device is obtained in which the semiconductor device according to any of the first through the third aspects is further provided with a plurality of conductive layers and a plurality of insulating layers alternately disposed (or formed), and a via disposed (formed) within the insulating layers; the external electrode pad is formed in a conductive layer positioned so as to be an uppermost layer among the conductive layers; a support pattern, having an area corresponding to the bonding area, is formed so as to be positioned directly below the bonding area, in a layer one layer below the uppermost layer, among the conductive layers; and a support via connecting the bonding area and the support pattern is formed between the uppermost layer and the layer one layer below the uppermost layer.

Furthermore, in a fifth aspect of the semiconductor device according to the present invention, a semiconductor device is obtained in which, in the semiconductor device according to the fourth aspect, the area of the support via is at least 50% and at most 90% of the area of the bonding area.

Furthermore, in a sixth aspect of the semiconductor device according to the present invention, a semiconductor device is obtained in which, in the semiconductor device according to the fourth or the fifth aspect, dummy patterns for ensuring flatness are formed in each corresponding region directly below the bonding area in layers outside of the uppermost layer and the layer one layer below the uppermost layer, among the conductive layers.

Furthermore, in a seventh aspect of the semiconductor device according to the present invention, a semiconductor device is obtained in which the semiconductor device according to any of the first through the sixth aspects is further provided with a substrate having a protection device region in which the ESD protection device is formed, and a dummy diffusion region for ensuring flatness in balance with the protection device region is formed in a corresponding region directly below the bonding area of the substrate.

Furthermore, in an eighth aspect of the semiconductor device according to the present invention, a semiconductor device is obtained in which the semiconductor device according to any of the first through the seventh aspects is further provided with a marker enabling distinguishing of the bonding area and the probing area, when the external electrode pad is viewed from above.

Furthermore, in an ninth aspect of the semiconductor device according to the present invention, a semiconductor device is obtained in which the semiconductor device according to the eighth aspect is further provided with an insulating film uniformly arranged on a layer in which the external electrode pad is formed, wherein an opening exposing the bonding area and the probing area, within the external electrode pad, is formed in the insulating film, and the opening has a form that enables functioning as the marker.

Furthermore, in a tenth aspect of the semiconductor device according to the present invention, a semiconductor device is obtained in which the semiconductor device according to the ninth aspect has the external electrode pad, the ESD protection device, and the opening as a set, and is provided with plural sets of the external electrode pad, the ESD protection device, and the opening; the plural sets of the external electrode pad, the ESD protection device, and the opening are arranged such that a plurality of the external electrode pads and a plurality of the openings are respectively arrayed in a straight line when the external electrode pads are viewed from above, and accordingly, a boundary of the bonding area and the probing area indicated by the marker is clear.

The meritorious effects of the present invention are summarized as follows.

According to the present invention, since the external electrode pad is divided into the bonding area and the probing area, it is possible to ensure bonding reliability, and in addition, since the ESD protection device is arranged below the probing area, it is possible to reduce chip size, in comparison to cases in which the ESD protection device is not arranged below the external electrode pad.

In addition, since the load on the probing area when probing is carried out is approximately a few grams, and is at least an order of magnitude less than the bonding load, the ESD protection device is not damaged by probing even if the ESD protection device is arranged below the probing area.

Therefore, according to the present invention, by both ensuring the bonding reliability and the prevention of damage to the ESD protection device by the bonding load, it is possible to realize a reduction in chip size.

### BRIEF DESCRIPTION OF THE DRAWINGS

FIG. 1 is a top view showing a vicinity of an external electrode pad of a semiconductor device according to a first exemplary embodiment of the present invention.

FIG. 2 is a sectional view showing the semiconductor device taken along a line II-II of FIG. 1.

FIG. 3 is a sectional view showing the semiconductor device taken along a line III-III of FIG. 1.

FIG. 4 is a top plan view showing a conductive layer, being a first layer (bottommost layer) of the semiconductor device of FIG. 1.

FIG. 5 is a top plan view showing a conductive layer, being a second layer of the semiconductor device of FIG. 1.

FIG. 6 is a top plan view showing a conductive layer, being a third layer (a layer one layer below an uppermost layer) of the semiconductor device of FIG. 1.

FIG. 7 is a top plan view showing a modified example of the vicinity of the external electrode pad of the semiconductor device of FIG. 1.

FIG. 8 is a sectional view showing the semiconductor device taken along a line VIII-VIII of FIG. 7.

FIG. 9 is a top view showing a vicinity of an external electrode pad of a semiconductor device according to a second exemplary embodiment of the present invention.

FIG. 10 is a view showing a state in which a plurality of external electrode pads, one of which is shown in FIG. 9, is arranged in a row.

FIG. 11 is a top plan view showing a vicinity of an external electrode pad of a semiconductor device according to a third exemplary embodiment of the present invention.

FIG. 12 is a view showing a state in which a plurality of external electrode pads, one of which is shown in FIG. 11, is arranged in a row.

### DETAILED DESCRIPTION OF THE PREFERRED EMBODIMENTS

### First Exemplary Embodiment

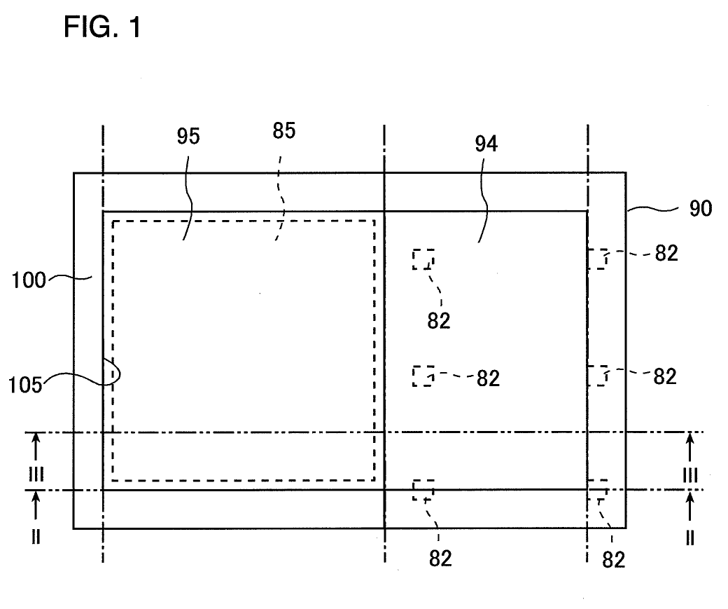

A semiconductor device according to a first exemplary embodiment of the present invention, as shown in FIG. 1 through FIG. 6, has four metal layers and is provided with an external electrode pad 90 in the fourth layer (uppermost layer). In outline, the external electrode pad 90 in the present exemplary embodiment, to avoid a bonding defect arising from contact damage of a probe needle when probing is carried out, separately has a bonding area 95, which is an area for wire bonding, and a probing area 94, which is an area to which the probe needle is applied when probing is carried out, and an ESD protection device is provided below the probing area 94.

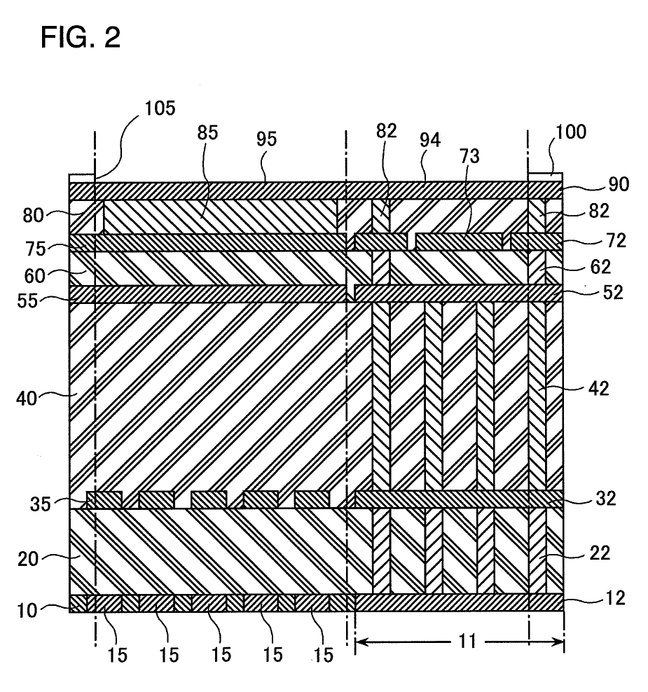

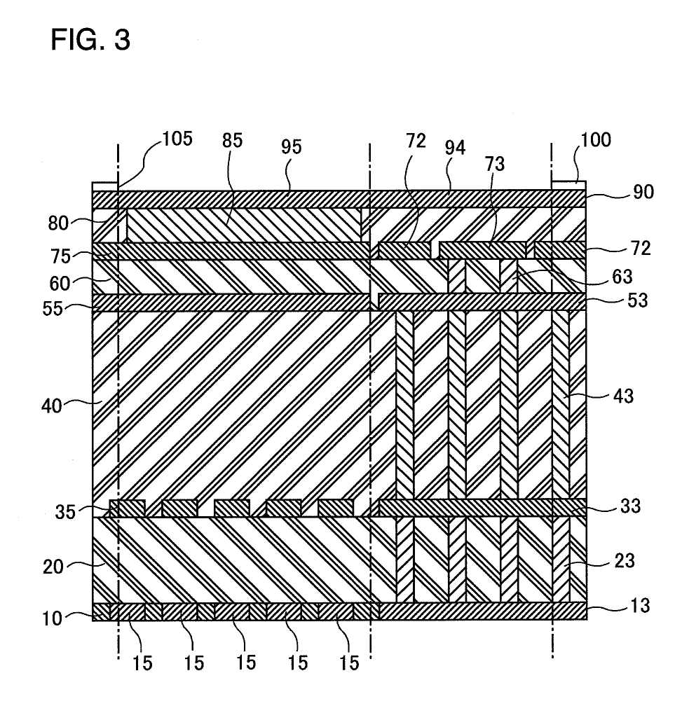

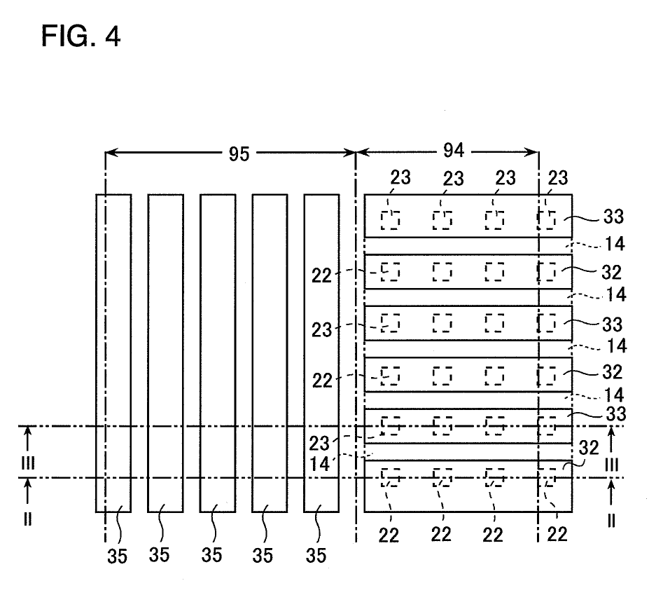

In detail, as shown in FIG. 2 and FIG. 3, the semiconductor device according to the present exemplary embodiment has a substrate 10. The substrate 10 is provided with a protection device region 11 forming an ESD protection device; and diffusion regions being a drain region 12 and a source region 13 of the ESD protection device are arranged alternately at a prescribed interval, in the protection device region 11. In this way, as may be understood from FIG. 2, FIG. 3, and FIG. 4, a gate region 14 is prescribed between the drain region 12 and the source region 13. The protection device region 11 formed from the drain region 12, the source region 13, and the gate region 14, as is clear from FIG. 2 and FIG. 3, is arranged below the probing area 94, so as not to be positioned directly below the bonding area 95. In order to ensure flatness of elements formed in an upper layer, in balance with the drain region 12 and the source region 13, dummy diffusion regions 15 are formed in a corresponding region of the substrate 10 directly below the bonding area 95. In the present exemplary embodiment, as the dummy diffusion regions 15, a plurality of diffusion regions in strip form is formed extending in a direction orthogonal to a longitudinal direction of the drain region 12 and the source region 13.

As shown in FIG. 2, FIG. 3, and FIG. 4, a metal wiring layer, being a first layer, is formed through an interlayer insulating film 20, on the substrate 10. This first metal wiring layer includes conductive patterns 32 provided above the drain region 12, conductive patterns 33 provided above the source region 13, and dummy patterns 35 formed below the bonding area 95. The conductive patterns 32, as shown in FIG. 2, are connected to the drain region 12 by contacts (vias) 22, and the conductive patterns 33, as shown in FIG. 3, are connected to the source region 13 by contacts (vias) 23. In addition, the dummy patterns 35 according to the present exemplary embodiment, as shown in FIG. 4, are formed of a plurality of strip regions, and each of these regions has a longitudinal direction the same as that of the dummy diffusion regions 15.

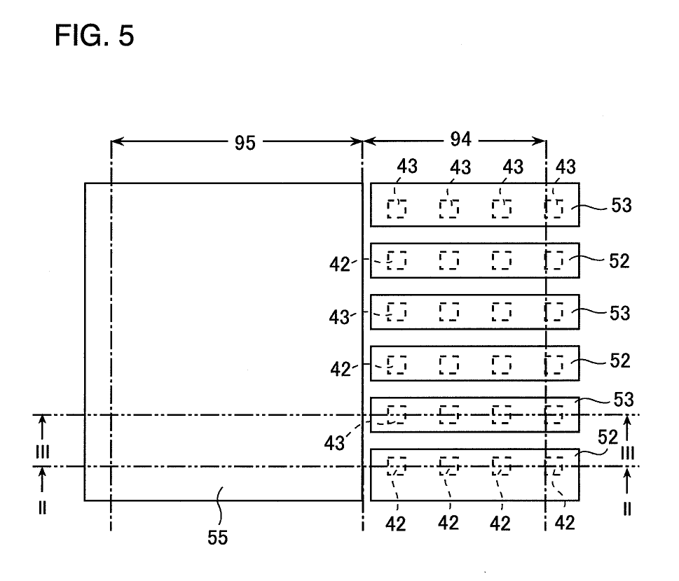

As shown in FIG. 2, FIG. 3, and FIG. 5, a metal wiring layer, being a second layer, is formed through an interlayer insulating film 40, on the first metal wiring layer, that is, on the conductive patterns 32 and 33, and the dummy patterns 35. The second metal wiring layer includes dummy patterns 52 and 53 formed on the probing area 94 side, and a dummy pattern 55 formed on the bonding area 95 side. The conductive patterns 52, as shown in FIG. 2, are connected to the conductive patterns 32 through plugs (vias) 42, and the conductive patterns 53, as shown in FIG. 3, are connected to the conductive patterns 33 through plugs (vias) 43. In addition, the dummy patterns 55 according to the present exemplary embodiment, as shown in FIG. 5, have an area corresponding to the bonding area 95.

Here, the above-mentioned dummy patterns 35 and the dummy pattern 55 are to ensure flatness, and as long as this object is realized, a form outside of the above-described form is also possible.

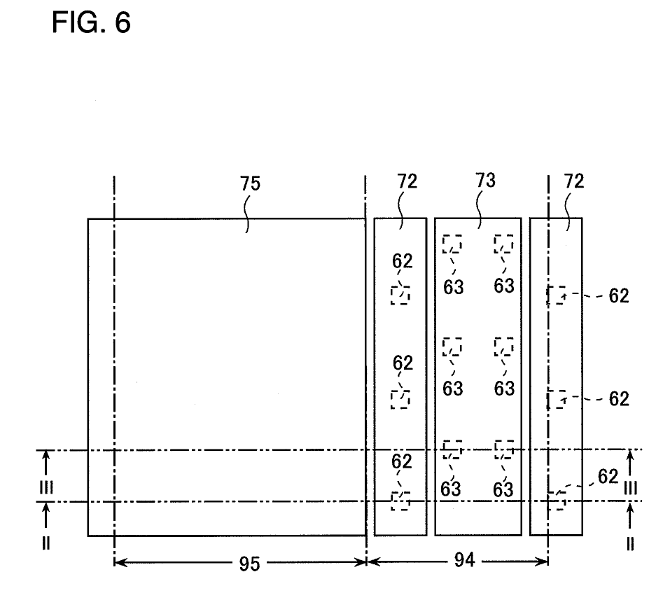

As shown in FIG. 2, FIG. 3, and FIG. 6, a metal wiring layer, being a third layer, is formed through an interlayer insulating film 60, on the second metal wiring layer, that is, on the conductive patterns 52 and 53, and the dummy pattern 55. The third metal wiring layer includes conductive patterns 72 and 73 formed on the probing area 94 side, and a support pattern 75 formed on the bonding area 95 side. The conductive patterns 72, as may be understood from FIG. 2 and FIG. 6, have strip forms extending in a direction orthogonal to the longitudinal direction of the drain region 12 and are connected to the conductive patterns 52 through plugs (vias) 62. The conductive pattern 73, as may be understood from FIG. 3 and FIG. 6, has a broad strip forms extending in a direction orthogonal to the longitudinal direction of the source region 13, and is connected to the conductive pattern 55 through plugs (vias) 63. That is, the conductive pattern 73, as shown in FIG. 3, is connected to the source region 13 of the ESD protection device, through the plugs 63, the conductive patterns 53, plugs 43, the conductive patterns 33, and the contacts 23. Furthermore, this conductive pattern 73 is connected to a VSS (not illustrated in the drawings), and functions as a discharge path. In addition, the conductive pattern 73, according to the present exemplary embodiment, as shown in FIG. 6, is positioned between two of the conductive patterns 72. The support pattern 75 according to the present exemplary embodiment, as may be understood from FIG. 1 through FIG. 3 and FIG. 6, has a form corresponding to the bonding area 95, and accordingly has an area corresponding to the bonding area 95, and is arranged to be positioned directly below the bonding area 95.

As shown in FIG. 1 through FIG. 3, a metal wiring layer, being a fourth layer (uppermost layer) including the external electrode pad 90, is formed through an interlayer insulating film 80, on the third metal wiring layer, that is, on the conductive patterns 72 and 73, and the dummy pattern 75. A polyimide film 100 is formed on the external electrode pad 90, and an opening 105 is formed on this polyimide film 100, such that the bonding area 95 and the probing area 94 are exposed.

A as shown in FIG. 1 and FIG. 2, the external electrode pad 90 is connected to the conductive patterns 72 through plugs (vias) 82. That is, the external electrode pad 90 is connected to the drain region 12 of the ESD protection device, through the plugs 82, the conductive patterns 72, the plugs 62, the conductive patterns 52, the plugs 42, the conductive patterns 32, and the contacts 22. In addition, the bonding area 95 of the external electrode pad 90 is connected to the support pattern 75 through a support via 85. Here, the support via 85 has a size slightly smaller than the bonding area 95 so as not to be in contact with the conductive patterns 72 or the plugs 82 on the ESD protection device side. Specifically, the support via 85 preferably has an area 90% or less than that of the area of the bonding area 95. On the other hand, in order that the bonding area 95 provides adequate support when bonding is performed, the support via 85 preferably has an area at least 50% of the bonding area 95, and more preferably has an area of 80% or more in order to effectively counterpart (or withstand) the pressure when bonding is performed.

As described above, in the semiconductor device according to the present exemplary embodiment, by separating the bonding area 95 and the probing area 94, it is possible to prevent bonding defects caused by contact damage by the probe needle, and it is possible to realize a reduction in chip size while avoiding damage to the ESD protection device due to bonding pressure, since the ESD protection device is arranged below the probing area 94. For example, in a general 70 nm process product, the area occupied by the ESD protection device is approximately 0.5% of the total, but in comparison to a case where the ESD protection device is formed separately from the external electrode pad 90, it is possible to realize a size reduction by that extent.

In addition, since the ESD protection device is arranged at a position close to the external electrode pad 90, the semiconductor device according to the present exemplary embodiment has a preferable characteristic from the viewpoint of a functional aspect of the ESD protection device.

Furthermore, since the support via 85 and the support pattern 75 are arranged directly below the bonding area 95, pressure when bonding is being performed can be withstood.

On the other hand, the plugs 82, the conductive patterns 72, the plugs 62, the conductive patterns 52, the plugs 42, the conductive patterns 32, and the contacts 22 are formed below the probing area 94 in order to connect the external electrode pad 90 and the drain region 12 of the ESD protection device; and the plugs 63, the conductive patterns 52, the plugs 43, the conductive patterns 33, and the contacts 23 are formed in order to connect the conductive pattern 73, which functions as a discharge path, to the source region 13 of the ESD protection device. In addition to the above-mentioned electrical connection, these also have a strengthening role in order to withstand pressure applied through the probing area 94 when probing is performed. In particular, in the present exemplary embodiment, four per each of the contacts 22, the contacts 23, the plugs 42, and the plugs 43 are arranged for (allocated to) each drain region 12 and source region 13 respectively, so that robust strengthening is obtained. In addition, by arranging the conductive pattern 73, which functions as a discharge path, at a position below the probing area 94, and which is the third metal wiring layer, uniformity of the third metal wiring layer is ensured.

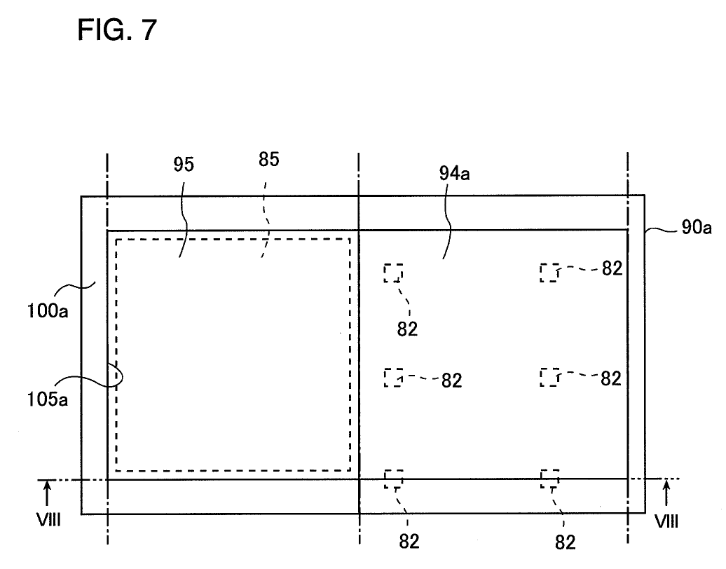

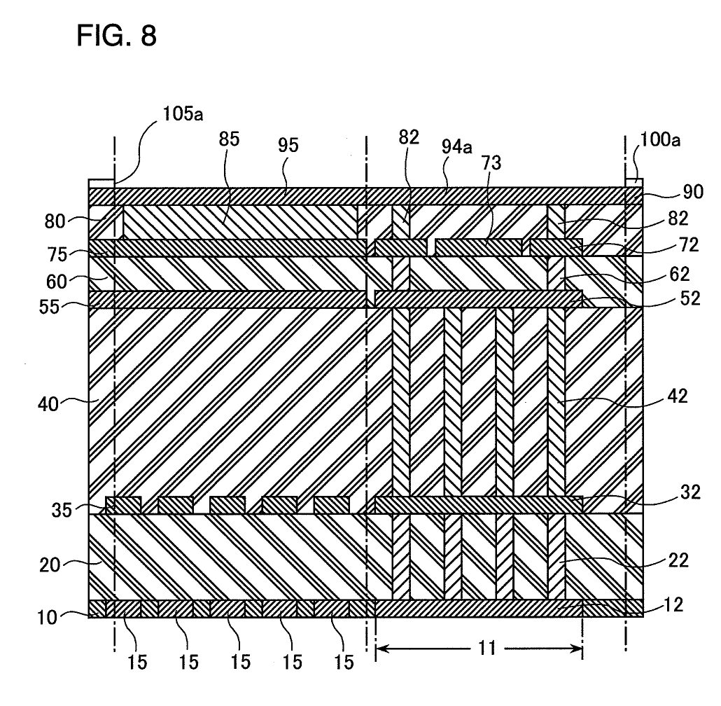

The semiconductor device according to the above-mentioned exemplary embodiment can be easily applied when there are differences in numbers of probes for each customer. Specifically, since the greater the number of times probing is carried out, the greater the contact damage due to probe needles, a wide probing area is required, but according to the present exemplary embodiment, cases in which it is desired to enlarge the probing area, that is, cases in which a semiconductor device is manufactured for a customer who performs a probe many times, can be easily reacted by changing only a pattern of the external electrode pad of the uppermost layer and a pattern of the opening of a polyimide layer. In comparison to the semiconductor device shown in FIG. 1 through FIG. 6, an example is shown in FIG. 7 and FIG. 8 in which the probing area 94a is enlarged by changing only the pattern of the external electrode pad 90a and the pattern of the opening 105a of the polyimide layer 100a.

### Second Exemplary Embodiment

A semiconductor device according to a second exemplary embodiment of the present invention is a modified example of the first exemplary embodiment as described above, and concretely, by having an opening of a polyimide film, formed on an external electrode pad, in a specific shape, the opening of the polyimide film has a function as a marker, enabling a bonding area and a probing area to be distinguished, when the external electrode pad is viewed from above. In the following, only points of difference from the semiconductor device according to the first exemplary embodiment are described, and descriptions of other points are omitted.

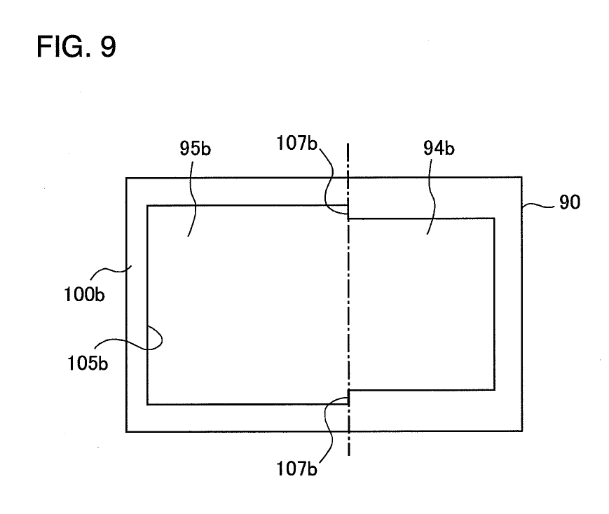

The semiconductor device according to the present exemplary embodiment is provided with the polyimide film 100b that has the opening 105b as shown in FIG. 9. Specifically, by making the opening width of the opening 105b different for the bonding area 95b and the probing area 94b, a step 107b is formed at a boundary portion of the bonding area 95b and the probing area 94b. Therefore, in cases of either testing or of bonding, with the step 107b of the opening 105b as a mark, it is possible to distinguish between the probing area 94b and the bonding area 95b, and to perform operations on each area as appropriate.

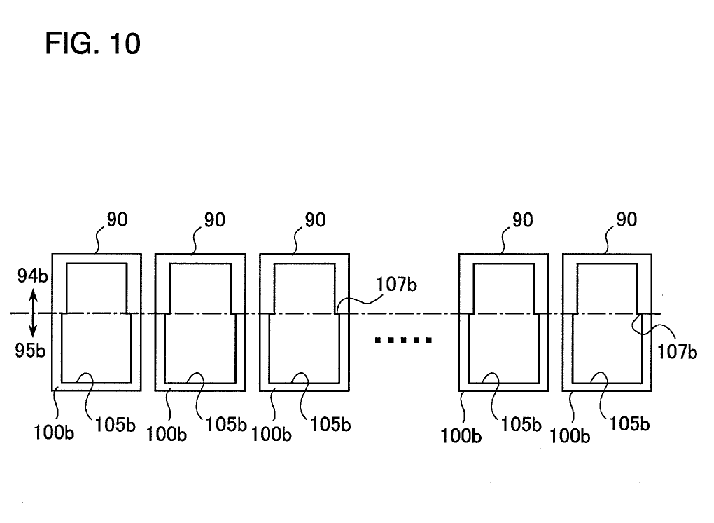

Normally, a plurality of external electrode pads 90 are arranged on the semiconductor device, and an ESD protection device is arranged on each of these; in such cases, for example, by placing a plurality of external electrode pads 90 and openings 105b of polyimide films 100b side by side in a straight line so that steps 107b are arrayed in a straight line, as shown in FIG. 10, with respect to sides of chips forming the semiconductor device, the boundary portions of the bonding areas 95b and the probing areas 94b may be understood at a glance.

### Third Exemplary Embodiment

A semiconductor device according to a third exemplary embodiment of the present invention is a modified example of the first exemplary embodiment similar to the second exemplary embodiment, and concretely, by making an opening of a polyimide film, formed on the external electrode pad, in a specific shape, the opening of the polyimide film has a function as a marker, enabling the bonding area and the probing area to be distinguished, when the external electrode pad is viewed from above. In the following, only points of difference from the semiconductor device according to the first exemplary embodiment are described, and descriptions of other points are omitted.

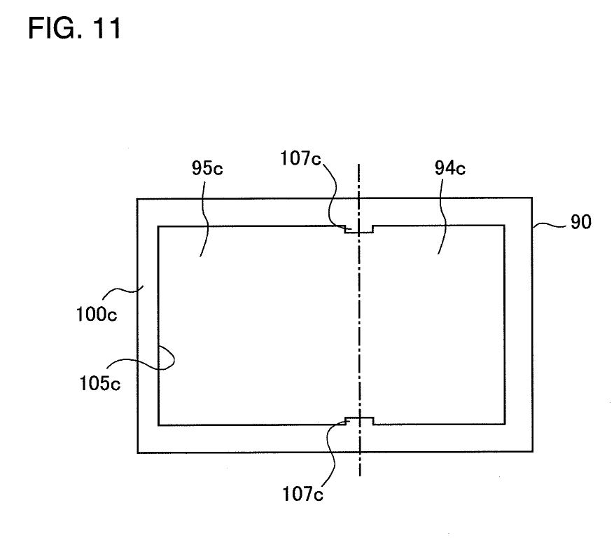

The semiconductor device according to the present exemplary embodiment is provided with a polyimide film 100c that has an opening 105c as shown in FIG. 11. Specifically, at a position equivalent to a boundary portion of a bonding area 95c and a probing area 94c, protruding parts 107c, protruding so as to face each other from two opposing sides of the opening 105c, are arranged in the polyimide film 100c. Therefore, in cases of either testing or of bonding, with the protruding parts 107c of the opening 105c as a mark, it is possible to distinguish between the probing area 94c and the bonding area 95c, and to perform operations on each area as appropriate.

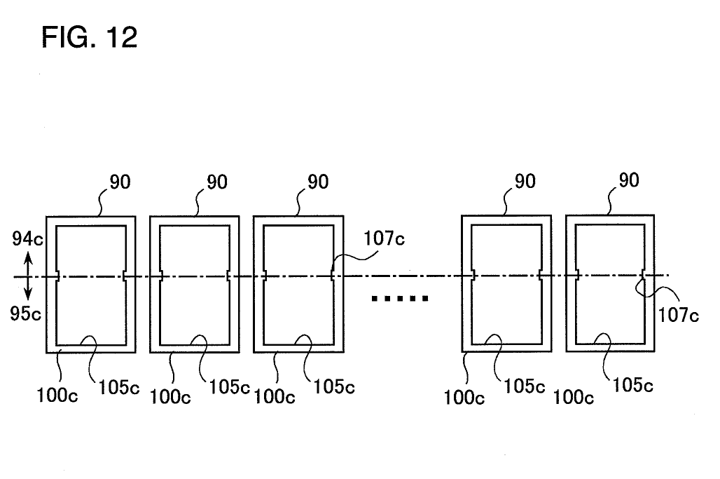

In the present exemplary embodiment, with regard to a plurality of external electrode pads 90, for example, by placing the plurality of the external electrode pads 90 and the openings 105c of the polyimide films 100c side by side in a straight line so that the protruding parts 107c are arrayed in a straight line, as shown in FIG. 12, the boundary portions of the bonding areas 95c and the probing areas 94c may be distinguished at a glance.

The present invention can be applied to a semiconductor device provided with ESD protection device and having an external electrode pad, as in DRAM.

In an eleventh aspect of the present invention, there is provided a semiconductor device, comprising: a bonding pad; and an insulating layer disposed on the bonding pad and having an opening to expose a part of the bonding pad, a first part of the opening being defined by first and second sides opposing to each other in a first direction, and a second part of the opening being defined by third and fourth sides opposing to each other in the first direction. A first distance between the first and second sides is different from a second distance between the third and fourth sides.

In a first mode for the eleventh aspect, the first and second sides may be the substantially same in length with each other and the third and fourth sides may be the substantially same in length with each other, and each of the first and second sides may be larger in length than each of the third and fourth sides.

In a second mode for the eleventh aspect, the first distance may be shorter than the second distance and a first portion of the bonding pad exposed by the first part of the opening may serve as a probe area with which a probe needle is to be in contact.

In a twelfth aspect of the present invention, there is provided a semiconductor device, comprising: a bonding pad; and an insulating layer disposed on the bonding pad, the insulating layer having a first opening to expose a part of the bonding pad, the first opening having a first width in a first direction, having a second opening to expose another part of the bonding pad, the second opening being extended continuously from the first opening in a second direction perpendicular to the first direction with a second width different from the first width.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor device comprising:
an external electrode pad having a bonding area that is an area for wire bonding and a probing area that is an area to which a probe needle is applied in probing; and
an ESD protection device positioned below said probing area and arranged to be electrically connected to said probing area.

2. The semiconductor device according to claim 1, wherein said ESD protection device is formed so as not to be positioned directly below said bonding area.

3. The semiconductor device according to claim 1, further comprising a discharge path connected to said ESD protection device, wherein
said discharge path is arranged so as not to be positioned directly below said bonding area.

4. The semiconductor device according to claim 1, comprising a plurality of conductive layers and a plurality of insulating layers alternately formed, and a via formed within said insulating layers, wherein
said external electrode pad is formed in a conductive layer positioned so as to be an uppermost layer among said conductive layers;
a support pattern, having an area corresponding to said bonding area, is formed so as to be positioned directly below said bonding area, in a layer one layer below said uppermost layer, among said conductive layers; and
a support via connecting said bonding area and said support pattern is formed between said uppermost layer and said layer one layer below said uppermost layer.

5. The semiconductor device according to claim 4, wherein the area of said support via is at least 50% and at most 90% of the area of said bonding area.

6. The semiconductor device according to claim 4, wherein dummy patterns for ensuring flatness are formed in each corresponding region directly below said bonding area in a layer outside of said uppermost layer and said layer one layer below said uppermost layer, among said conductive layers.

7. The semiconductor device according to claim 1, further comprising a substrate having a protection device region in which said ESD protection device is formed, wherein
a dummy diffusion region for ensuring flatness in balance with said protection device region, is formed in a corresponding region directly below said bonding area of said substrate.

8. The semiconductor device according to claim 1, further comprising a marker enabling distinguishing of said bonding area and said probing area, when said external electrode pad is viewed from above.

9. The semiconductor device according to claim 8, further comprising an insulating film uniformly arranged on a layer in which said external electrode pad is formed, wherein
an opening exposing said bonding area and said probing area, within said external electrode pad, is formed in said insulating film, and
said opening has a form that enables functioning as said marker.

10. The semiconductor device according to claim 9, comprising, with said external electrode pad, said ESD protection device, and said opening as a set, plural sets of said external electrode pad, said ESD protection device, and said opening, wherein
said plural sets of said external electrode pad, said ESD protection device, and said opening are arranged such that a plurality of said external electrode pads and a plurality of said openings are respectively arrayed in a straight line when said external electrode pads are viewed from above, and accordingly, a boundary of said bonding area and said probing area indicated by said marker is clear.

11. A semiconductor device, comprising:
a bonding pad; and
an insulating layer disposed on said bonding pad and having an opening to expose a part of the bonding pad, a first part of the opening being defined by first and second sides opposing to each other in a first direction, and a second part of the opening being defined by third and fourth sides opposing to each other in the first direction; a first distance between said first and second sides being different from a second distance between said third and fourth sides.

12. The semiconductor device according to claim 11, wherein said first and second sides are the substantially same in length with each other and said third and fourth sides are the substantially same in length with each other, and each of said first and second sides is larger in length than each of said third and fourth sides.

13. The semiconductor device according to claim 12, wherein said first distance is shorter than said second distance and a first portion of said bonding pad exposed by said first part of said opening serves as a probe area with which a probe needle is to be in contact.

14. A semiconductor device, comprising:
a bonding pad; and
an insulating layer disposed on said bonding pad, said insulating layer having a first opening to expose a part of said bonding pad, said first opening having a first width in a first direction, having a second opening to expose another part of said bonding pad, said second opening being extended continuously from said first opening in a second direction perpendicular to said first direction with a second width different from said first width.
